(19) United States
(12) Patent Application Publication
(10) Pub. No.: US 2026/0105946 A1
(43) Pub. Date: Apr. 16, 2026

(54) SYSTEMS AND METHODS FOR ADJUSTABLE POLLING OF REFRESH FLAG BASED ON TRAFFIC TO MEMORY DEVICE

(71) Applicant: Micron Technology, Inc., Boise, ID (US)

(72) Inventors: Sujeet Ayyapureddi, Boise, ID (US); Gary Howe, Allen, TX (US)

(73) Assignee: Micron Technology, Inc., Boise, ID (US)

(21) Appl. No.: 19/337,784

(22) Filed: Sep. 23, 2025

Related U.S. Application Data
(60) Provisional application No. 63/708,163, filed on Oct. 16, 2024.

(51) Int. Cl. G11C 11/406; G11C 11/408; G11C 11/4096

(52) U.S. Cl. CPC G11C 11/40615; G11C 11/4087; G11C 11/4096

(57) ABSTRACT

Techniques for adjusting a frequency at which a memory controller polls a refresh flag are disclosed. Traffic counters are maintained to track traffic to portions of a memory device. A traffic balance is computed using the traffic counters, which indicates a distribution of the traffic to the portions of the memory device. For example, where access operations are performed equally in two halves of a memory bank, the traffic to the memory bank is equally balanced. In memory devices implementing background refresh traffic technology, high traffic balance may indicate that a memory device is likely to be adequately refreshed because opportunities for background refresh operations are evenly distributed. As a result, a memory controller may reduce the frequency at which a refresh flag of the memory is polled when the total traffic exceeds a threshold and when the traffic balance exceeds a threshold.

### CROSS-REFERENCE TO RELATED APPLICATIONS

This application claims the filing benefit of U.S. Provisional Application No. 63/708,163, filed Oct. 16, 2024. This application is incorporated by reference herein in its entirety and for all purposes.

### BACKGROUND

This disclosure relates generally to semiconductor devices, and more specifically to semiconductor memory devices. Disclosed embodiments relate to volatile memory, such as dynamic random-access memory (DRAM). Information is stored on memory cells as a physical signal, such as a charge on a capacitive element. The memory cells may be organized at the intersection of word lines (rows) and bit lines (columns). Information in the memory cells may decay over time. In order to preserve the integrity of the stored information, the memory device may perform refresh operations to restore the information and prevent information from being lost.

### BRIEF DESCRIPTION OF THE DRAWINGS

FIG. 1 is a block diagram illustrating a memory system according to embodiments of the disclosure.

FIG. 2 is a block diagram illustrating bank logic circuits according to embodiments of the disclosure.

FIG. 3 is a table illustrating adjustable polling frequencies based on traffic balance according to embodiments of the disclosure.

FIG. 4 is a flow diagram illustrating a process for setting an adjustable polling frequency based on a traffic count according to embodiments of the disclosure.

FIG. 5 is a flow diagram illustrating a process for setting an adjustable polling frequency based on a traffic count and a traffic balance according to embodiments of the disclosure.

FIG. 6 is a flow diagram illustrating a process for determining a traffic balance according to embodiments of the disclosure.

### DETAILED DESCRIPTION

The present disclosure provides descriptions of non-limiting example embodiments and is in no way intended to limit the scope of the disclosure or its applications or uses. In the following detailed description of embodiments of the present technology, reference is made to the accompanying drawings, which form a part hereof and in which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art, so as not to obscure the description of embodiments of the disclosure. The following detailed description is therefore not to be taken as limiting, and the scope of the disclosure is defined only by the appended claims.

A memory device includes a memory array. The memory array includes a number of memory cells at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

Information in a memory array may be accessed by performing access operations, such as read or write operations. During an example access operation, a word line may be activated based on a row address. Selected memory cells along that active word line may have their information read from, or written to, based on which bit lines are selected by a column address. The bit lines are coupled to sense amplifiers. The sense amplifiers sense a voltage on the bit line from the memory cells along the active word line and amplify it into a signal in a read operation or drive a voltage to the memory cell along the active word line in a write operation. Each bank is divided into sections. In some embodiments, a bank is divided into sections, with each section separated from its neighboring sections by a strip of sense amplifiers that are coupled to the bit lines extending into the neighboring sections. Accordingly, the row address may specify which section is being accessed. The sense amplifiers are shared by the neighboring sections, with the sense amplifiers used by one of the neighboring sections during an access operation.

Information in the memory cells decays over time. To prevent information loss, the memory array may be refreshed on a row-by-row basis (e.g., as part of an auto-refresh and/or self-refresh mode), where the memory cells along each row are refreshed periodically to restore the stored information to an initial value. Such refresh operations may be referred to as sequential refresh operations or normal refresh operations, as the memory may use some sequence logic (e.g., a counter) to generate refresh addresses used to determine which word lines are refreshed. Targeted refresh operations may be performed to refresh word lines associated with aggressor word lines.

In some examples, background refresh operations may be performed, which may refresh targeted word lines or word lines identified using sequence logic. In a background refresh operation, a memory device receives an access operation which allows an opportunity for a refresh operation on memory cells other than the memory cells that are accessed for the access operation. For example, the memory determines if a refresh operation is needed and possible, and then performs a refresh operation on a word line in a different section than the section being accessed. The word lines may be active at overlapping periods of time. In this way, refreshes may occur while the memory is being accessed. By contrast, refresh operations performed on their own, such as in response to a refresh command from a controller, may generally be referred to as standalone refresh operations. The use of background refresh operations may help decrease the number of standalone refresh operations. The use of background refresh operations may decrease a downtime of the memory because both access operations and refresh operations may be performed, unlike standalone refresh operations, which may not allow for access operations.

A memory device may track how many refresh operations have been performed (e.g., in one or more banks, in one or more sections of a bank, across the memory device) compared to how many refresh operations are expected to be performed in order to generate a refresh deficit count, and the refresh deficit count may be used by the memory device to determine whether a refresh operation should be performed. For example, the memory device may be configured to expect at least a threshold number of refresh operations to be performed in a time interval (e.g., one or more refresh intervals (tREFI)), and the refresh deficit count may indicate when the number of actual refresh operations does not satisfy the threshold number. The memory device may use the refresh deficit count to determine when to perform a refresh operation either for background refresh operations or for refresh operations performed responsive to a refresh command. In various examples, the refresh deficit count may be used to set a refresh flag, which may be stored in a mode register of the memory device. For example, when a refresh deficit count (e.g., for a bank, for a section, for all banks) exceeds a threshold value, the memory device may set the refresh flag to indicate that a refresh operation is needed. Additionally or alternatively, the refresh flag may be provided at an active level to indicate that a count of refresh operations is below a threshold value, such as an expected number of refresh operations in a time period.

A memory controller coupled to the memory device may perform a mode register read command (e.g., periodically) to poll the refresh flag. When the memory controller determines that the refresh flag is active, the memory controller issues a refresh command to cause performance of a refresh operation at the memory device. In some examples, a refresh flag is provided per bank of the memory device, and the memory controller provides a refresh command when at least one refresh flag is active (e.g., when at least one deficit count is above zero). The memory controller may determine a type of refresh command to provide. For example, if only a single bank has set a respective refresh flag, the memory controller may determine that a per-bank refresh command will be issued for the respective bank. The refresh command may cause the memory device to perform a standalone refresh operation.

Embodiments disclosed herein include systems, methods, and apparatuses for adjusting a frequency at which a memory controller polls a refresh flag. In various embodiments, one or more traffic counters can be used to track an amount of traffic (e.g., access operations) to one or more portions of a memory device. The traffic counters can also be used to determine a traffic balance, which indicates a distribution of traffic across the one or more portions of the memory device. For example, a computed traffic balance may indicate whether access operations are being performed relatively evenly (e.g., 80% traffic balance, 90% traffic balance, 100% traffic balance) across two portions (e.g., halves) of a bank of a memory device. In some embodiments, the one or more traffic counters are maintained by a memory controller.

As used herein, “traffic” can refer to a quantity of operations (e.g., access operations) performed at one or more portions of a memory device and/or across a memory device during a time interval (e.g., one or more intervals tREFI). As used herein, “traffic balance” can refer to a distribution of traffic across one or more portions of a memory device and/or across a memory device. For example, a traffic balance can indicate traffic in a first portion of a memory bank relative to a second portion of the memory bank. In memory devices implementing background refresh technology, high traffic balance (e.g., 80%, 90%, 100%) may be an indication that a respective bank of a memory device is likely to be adequately refreshed because the evenly distributed access operations may correspond to an even distribution of background refresh opportunities, such that refreshes are also being performed relatively evenly across the respective bank. By contrast, low traffic balance (e.g., 0%, 10%, 20%) may be an indication that at least a portion of the respective bank of the memory is not being adequately refreshed because opportunities for performing background refresh operations will be similarly unevenly distributed. In disclosed embodiments, traffic to one or more portions of a memory device is tracked using traffic counters (e.g., for respective portions of a memory bank), and a traffic balance is determined based on the traffic counters. Polling logic adjusts a frequency at which the memory controller reads the refresh flag based on a quantity of traffic and/or the traffic balance. For example, the refresh flag is polled more frequently when the memory device is more likely to need a refresh command and less frequently when the memory device is less likely to need a refresh command (e.g., because the quantity and distribution of traffic provides adequate opportunities for background refresh operations across the memory device). In various embodiments, the polling frequency is reduced when total traffic (e.g., to one or more banks) exceeds a threshold quantity and the traffic balance (e.g., to the one or more banks) exceeds a threshold.

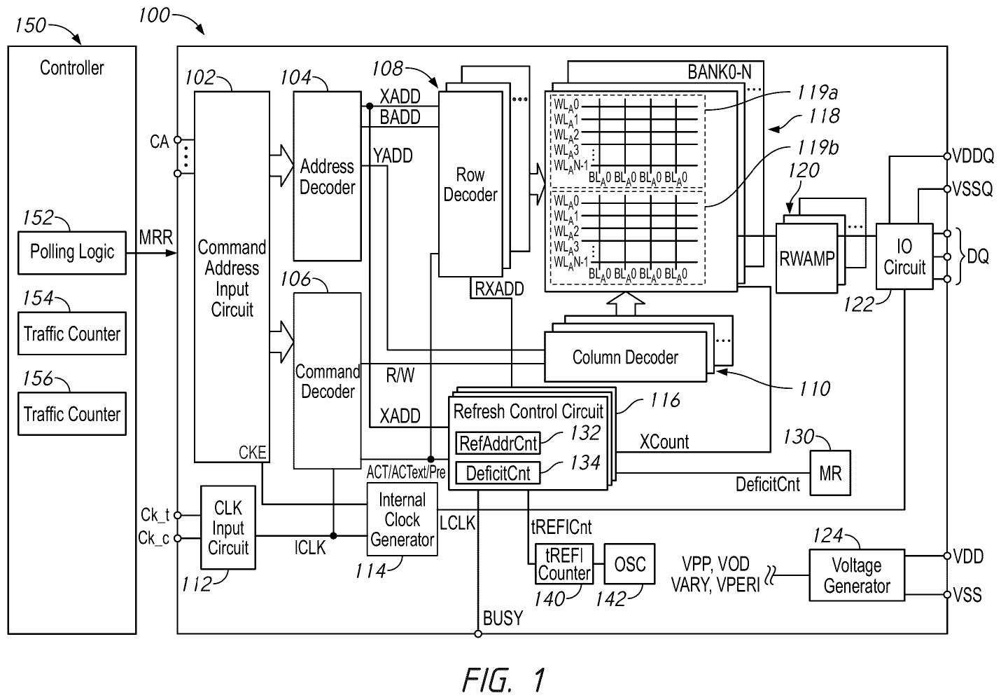

FIG. 1 is a block diagram illustrating a memory system according to embodiments of the disclosure. The memory system includes a memory device 100 and a memory controller 150. The memory device 100 may be, for example, a DRAM device integrated on a single semiconductor chip. The memory device 100 may be operated by the memory controller 150. In some embodiments, the memory controller 150 and the memory device 100 may be packaged together on a single integrated circuit. In some embodiments, the memory controller 150 and the memory device 100 may be separate. In some embodiments, the memory controller 150 may operate multiple memory devices 100.

The memory device 100 includes a memory array 118. The memory array 118 may be organized into one or more memory banks. In the embodiment of FIG. 1, the memory array 118 is shown as including N memory banks BANK0-BANKN-1. For example there may be 2, 4, 8, or 16 memory banks. More or fewer banks may be included in the memory array 118 of other embodiments. Each memory bank includes a plurality of word lines WL (rows), a plurality of bit lines BL (columns), and a plurality of memory cells arranged at intersections of the plurality of word lines WL and the plurality of bit lines BL. Each bank is associated with a value of a bank address BADD.

The selection of the word line WL is performed by bank row decoders 108 and the selection of the bit lines BL is performed by a column decoder 110. Certain circuits, such as the bank row decoders 108 and the column decoder 110 are repeated on a bank-by-bank basis. For example, if there are N banks there may be N bank row decoders 108 and N column decoders 110. Certain other circuits of the memory device 100 may also be repeated on a bank-by-bank basis. For example, each bank may have an associated bank logic region, which includes the circuits associated with that bank.

The bit lines BL are coupled to a respective sense amplifier (SAMP). The sense amplifiers are coupled to local input/output (LIO) and global input/output (GIO) to read/write amplifiers (RWAMP) 120 and through those to the input/output circuits 122 of the memory device 100. During an access operation, the bank row decoder circuits 108 activate a word line specified by the row address. The activated word line couples the memory cells along that word line to the intersecting bit lines. During a read operation, the sense amplifiers amplify the signal along that bit line to a voltage that represents the logical level stored in the memory cell. During a write operation, the sense amplifiers receive a signal indicating a logical level to be written and amplify it onto the bit line and through the bit line to the memory cell. After operations, the bank row decoder circuits 108 pre-charge the word line.

The banks may be divided into one or more portions 119. For example, FIG. 1 shows two portions 119a and 119b, each with their own respective set of word lines WL_{A} and WL_{B} and their own respective set of bit lines BL_{A} and BL_{B.} The different portions may have a same or different number of word lines, bit lines, or combinations thereof. The portions 119 may be address spaces, and the portions 119 may be identified based on row addresses. One or more bits of the row address XADD may specify which portion to perform the access operation in. More portions per bank may be used in other example embodiments.

The memory device 100 includes a mode register 130. The mode register includes a number of storage elements, such as latch circuits, organized in registers. The registers store information such as settings of the memory, information about the memory, or combinations thereof. For example, in some embodiments, the mode register 130 stores one or more refresh flags. The refresh flags stored by the mode register 130 may indicate that one or more refresh operations are needed. The memory controller 150 may perform a mode register read (MRR) operation to retrieve information from a specified register or a mode register write (MRW) operation to write information to a specified register. Some registers may be read only to prevent the memory controller 150 from modifying them. Some registers may be updated based on conditions or operations of the memory.

The memory device 100 may employ a plurality of external terminals coupled to the controller. The external terminals include command and address (CA) terminals coupled to the memory controller 150 along a command and address bus to receive commands and addresses. Other external terminals include clock terminals to receive clock signals CK_t and CK_c along a clock bus, data terminals DQ to send and receive data along a data bus, and power supply terminals to receive power supply potentials such as VDD, VSS, VDDQ, and VSSQ.

The clock terminals are supplied by the memory controller 150 with external clocks CK_t and CK_c that are provided to an input circuit 112. The external clocks may be complementary. The input circuit 112 generates an internal clock ICLK based on the CK_t and CK_c. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The CA terminals may be supplied with memory addresses by the memory controller 150. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include access commands such as an activate command ACT, one or more column commands such as read or write, and pre-charge command PRE, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations.

As part of an example write operation, the CA terminals receive an activate command ACT and a row address. The row address includes one or more bits which specify which portion 119 to activate. The row decoder 108 activates the specified word line. The row decoder 108 may also activate a word line in the non-selected portion and perform a background refresh operation in one or more rows in the non-selected portion (e.g., based on a background refresh command provided by the refresh control circuit 116), such as to refresh a row identified by the refresh control circuit 116. The CA terminals receive a column command, in this case write, along with a column address. The column decoder couples bit lines specified by the column address YADD to the LIO and GIO lines. The input/output circuit 122 receives data along the data terminals DQ. The data is provided through the RWAMP 120 through the LIO and GIO lines to the specified bit lines. When the controller is done performing operations on the word line, the memory device 100 receives a pre-charge command PRE, and the active word lines are pre-charged.

As part of an example read operation, the CA terminals receive an activate command ACT and a row address. The row address includes one or more bits which specify which portion 119 to activate. The row decoder 108 activates the specified word line. The row decoder 108 may also activate a word line in the non-selected portion and perform a background refresh operation in one or more rows in the non-selected portion (e.g., based on a background refresh command provided by the refresh control circuit 116), such as to refresh a row identified by the refresh control circuit 116. The CA terminals receive a column command, in this case read, along with a column address. The column decoder couples bit lines specified by the column address YADD to the LIO and GIO lines. The sense amplifiers amplify the signal from the intersecting memory cells along the bit lines to the LIO and GIO lines through the RWAMP 120 to the IO circuit 122. The IO circuit 122 provides the read data to the data terminals DQ. When the memory controller 150 is done performing operations on the word line, the memory device 100 receives a pre-charge command PRE, and the active word lines are pre-charged.

The memory device 100 may also receive commands causing it to carry out standalone refresh operations. For example, the memory controller 150 may issue a refresh command REF or a refresh management command RFM. Responsive to either the REF command or the RFM command, the refresh control circuit 116 may perform one or more refresh operations. As part of a refresh operation, the refresh control circuit 116 issues a refresh address RXADD, and the bank row decoder circuits 108 may refresh one or more word lines based on the refresh address RXADD. The number and type of refresh operations performed may vary based on whether REF or RFM is received. In some embodiments, the refresh control circuit 116 may be repeated on a bank-by-bank basis, similar to the row decoder 108 and the column decoder 110.

The refresh commands REF and RFM are supplied to the refresh control circuit 116. The refresh control circuit 116 supplies one or more refresh addresses RXADD to the row decoder 108, which refreshes one or more word lines WL identified by the refresh row address RXADD. For example, in some embodiments, the refresh control circuit 116 may perform a mix of normal (or sequential) refresh operations and targeted refresh operations responsive to the refresh command REF, and may perform targeted refresh operations responsive to the RFM command RFM. In some embodiments, the refresh control circuit 116 may perform normal refresh operations responsive to REF and targeted refresh commands responsive to RFM.

The refresh control circuit 116 may also perform background refresh operations. When the refresh control circuit 116 determines that there is a refresh opportunity for a bank, the refresh control circuit 116 determines whether or not to perform a refresh operation. For example, the refresh control circuit 116 may determine whether or not to perform a refresh operation based at least in part on if a refresh operation is called for, and if a refresh operation is possible. If the refresh control circuit 116 determines to perform a background refresh operation, the refresh control circuit 116 performs a background refresh operation by generating a refresh address RXADD. The row decoder 108 refreshes a word line associated with RXADD while the word line associated with XADD is being accessed as part of the access operation. In some embodiments, the memory device 100 can also receive a refresh command separate from an access command. Responsive to a refresh command, the refresh control circuit 116 determines whether or not to perform a refresh operation and generates RXADD. However, if a refresh operation is performed responsive to a refresh command, it is a standalone refresh operation on the word line associated with RXADD, and no other different word line is accessed. In some embodiments, multiple word lines may be specified by the refresh address RXADD and the row decoder 108 may refresh all of the word lines associated with RXADD.

The refresh control circuit 116 includes one or more refresh address counter circuits 132, which are used to generate a refresh address RXADD. Each time a refresh operation is performed, the refresh address counter 132 is updated (e.g., incremented) to generate a new value. In this way, the refresh address RXADD counts through the word lines of the bank.

The memory device 100 includes a refresh period counter 140. The memory device 100 may need to perform a certain number of refresh operations in a refresh window. For example, the memory device 100 may need to perform J refresh operations in a refresh window of K ms. In some embodiments, the value of the number of refresh operations (J), the value of the length of the refresh window (K), or combinations thereof, may be set based on values in the mode register 130, such as a refresh setting, a temperature of the memory, or combinations thereof. The memory device 100 sets a refresh interval tREFI based on the average interval between refresh operations in order to perform J operations in K amount of time. For example, tREFI=K/J. The refresh period counter 140 updates a refresh period count tREFIcnt every tREFI amount of time. The refresh period counter 140 may be coupled to an oscillator circuit 142, to a clock signal, or combinations thereof to count time. The tREFI counter 140 may reset the count tREFIcnt to an initial value at power up/reset or when the count reaches J. In this way the refresh interval count may represent a number of refreshes which should have been performed so far in the current refresh window.

The refresh address counter 132 tracks a number of refresh operations that have been performed. The refresh address counter 132 tracks a refresh address count RefAddrCnt, which may be used to generate the refresh address RXADD. In some embodiments, the refresh address count RefAddrCnt may be used as the refresh address RXADD directly. In some embodiments, the refresh control circuit 116 may generate the refresh address RXADD based on the refresh address count RefAddrCnt. The refresh control circuit 116 compares the refresh address count RefAddrCnt to the refresh interval count tREFIcnt. Based on that comparison, the refresh control circuit 116 sets a refresh deficit count DeficitCnt 134. The refresh deficit count DeficitCnt 134 may be stored in storage elements of the memory device 100 such as in register circuits or latch circuits. In some embodiments, if the refresh address count RefAddrCnt is equal to or greater than tREFIcnt, then the refresh deficit count DeficitCnt 134 is set to 0. If the refresh address count RefAddrCnt is less than tREFIcnt, then the refresh deficit count DeficitCnt 134 is set to the difference between tREFIcnt and RefAddrCnt. The refresh deficit count DeficitCnt 134 may be used as a refresh flag, or a refresh flag may be set (e.g., in the mode register 130) based on the refresh deficit count DeficitCnt.

The refresh control circuit 116 uses the refresh deficit count DeficitCnt 134, in part, to determine whether or not to perform a refresh operation. For example, if the deficit count DeficitCnt is 0, then a refresh operation may be skipped, even if the refresh control circuit 116 receives a refresh opportunity. If the deficit count is non-zero, then a refresh operation may be performed when the refresh control circuit 116 is presented with a refresh opportunity. In this manner, each bank or each portion of a bank as described in more detail herein, may be able to determine whether or not to perform a refresh when given the opportunity to do so, either responsive to an access operation or responsive to a refresh command from the memory controller 150. In some embodiments, a refresh may be performed even if the deficit count is zero. For example, the memory device 100 may perform up to a threshold number of operations even when the deficit count is zero in order to get ahead of the expected number of refreshes.

The refresh control circuit 116 sets a refresh flag in the mode register 130 based on the refresh deficit count DeficitCnt 134. For example, the refresh control circuit 116 may write the refresh deficit count DeficitCnt 134 to the mode register 130, and a deficit count DeficitCnt 134 greater than zero may be considered a refresh flag that is activated. Alternatively, the refresh flag may be a binary value that is set to an active level when the refresh deficit count DeficitCnt 134 is greater than zero. In either embodiment, the memory controller 150 may perform mode register read (MRR) operations to read the refresh flag for each of the banks from the mode register 130.

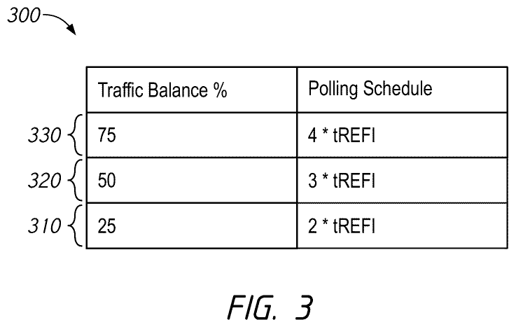

The memory controller 150 includes a polling logic circuit 152 that determines when to perform a MRR operation to determine the current status of the refresh flag in the mode register 130. Additionally, the memory controller 150 includes a traffic counter 154 and a traffic counter 156, which are used to track traffic (e.g., access operations) to the memory array 118. In an example implementation, the traffic counter 154 is used to maintain a count of access operations to the portion 119a, and the traffic counter 156 is used to maintain a count of access operations to the portion 119b. The traffic counter 154 may be incremented when one or more bits of a row address XADD associated with an access command correspond to the portion 119a, and the traffic counter 156 may be incremented when one or more bits of a row address XADD associated with an access command correspond to the portion 119b. Traffic counts maintained by the traffic counter 154 and the traffic counter 156 may indicate a number of access operations to respective portions 119 during a number of time intervals tREFI (e.g., most recent tREFI intervals). Using the traffic counters 154 and 156, the polling logic circuit 152 may determine traffic balance across one or more banks of the memory array 118. The polling logic circuit 152 may adjust a frequency of MRR operations to read the refresh flag based on traffic count values and traffic balance. For example, when a traffic count value of the traffic counter 154 is equal to a traffic count value of the traffic counter 156, the traffic balance is high (100% traffic balance), which indicates that access operations are being performed evenly across the portions 119 and background refresh opportunities are also distributed evenly across the portions 119. As a result, it is unlikely that standalone refresh operations are needed, and the polling logic circuit 152 may decrease the frequency of polling of the refresh flag. By contrast, when the traffic count value of the traffic counter 154 is greater than the traffic count value of the traffic counter 156 (or vice versa), the traffic balance is less than 100%, which indicates that more access operations are being performed in one portion 119 and background refresh opportunities are similarly unevenly distributed. As a result, it may be more likely that standalone refresh operations are needed, and the polling logic circuit 152 may increase the frequency of polling of the refresh flag. In various embodiments, the frequency of polling the refresh flag may increase as the traffic balance decreases. In various embodiments, the frequency of polling the refresh flag is based on both the traffic balance and total traffic (e.g., the sum of the traffic counter 154 and the traffic counter 156), for example, such that the polling frequency increases as the traffic balance decreases, when the total traffic is below a threshold, or both. The polling frequency may specify a rate at which the refresh flag will be read as a multiple of tREFI (e.g., once per tREFI, once every two tREFI, once every three tREFI, etc.). Examples of traffic balance and corresponding polling frequency are further described with reference to FIGS. 3-6. Although the traffic counters 154 and 156, and the polling logic circuit 152 are described with reference to FIG. 1 as being included in the memory controller 150, in other embodiments, one or more traffic counters, and/or polling logic circuit(s) are included in one or more other components of a memory system. As such, the disclosure is not limited to embodiments where traffic counters and/or polling logic circuits are included in a memory controller.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

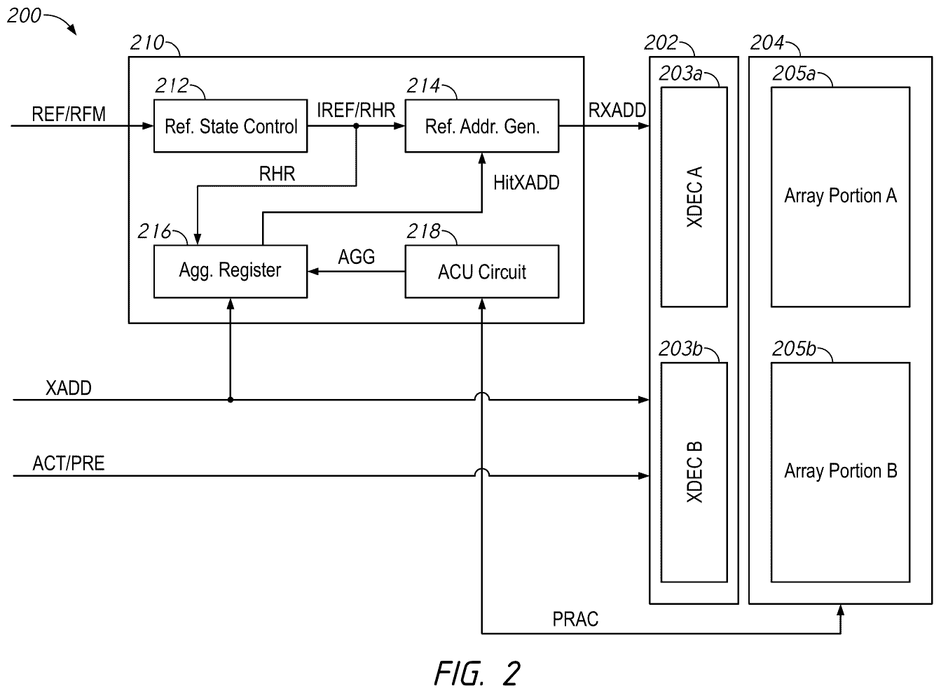

FIG. 2 is a block diagram illustrating bank logic circuits 200 according to embodiments of the disclosure. The bank logic circuits 200 may, in some embodiments, implement a part of a memory device such as 100 of FIG. 1. For example, the bank logic circuits 200 may represent selected circuits in a bank logic region associated with a bank of the memory array 118 of FIG. 1. The bank logic circuits 200 illustrated in FIG. 2 include a refresh control circuit 210 (e.g., 116 of FIG. 1), a row decoder 202 (e.g., 108 of FIG. 1), and a memory bank 204 (e.g., included in 118 of FIG. 1). Certain other circuits that may be part of the bank logic are omitted from the view of FIG. 2 for ease of illustration.

The refresh control circuit 210 includes a refresh state control circuit 212, a refresh address generator 214, an aggressor register 216, and an access count update (ACU) logic circuit 218. The refresh state control circuit 212 receives signals such as REF and RFM and determines how many refresh operations should be performed and what types. Additionally, the refresh state control circuit 212 may cause performance of background refresh operations associated with access operations. The refresh address generator circuit 214 generates the refresh address RXADD. The aggressor register 216 stores one or more identified aggressor addresses HitXADD. The ACU logic circuit 218 updates a per row activation counting PRAC value when a word line is accessed and uses the PRAC value to determine if the word line is an aggressor. The memory bank 204 is split into a portion 205a (e.g., 119a of FIG. 1) associated with a row decoder 203a (e.g., 109a of FIG. 1) and a portion 205b (e.g., 119b of FIG. 1) associated with a row decoder 203b (e.g., 109b of FIG. 1).

The refresh state control circuit 212 receives signals such as REF and RFM and determines how many refresh operations to perform and of what type(s). The refresh state control circuit 212 may also cause performance of background refresh operations, which may be performed without receiving the signals REF and RFM. The refresh state control circuit 212 provides an internal refresh signal IREF to indicate a normal refresh operation and a targeted refresh signal RHR to indicate a targeted refresh operation. In some example implementations, the refresh state control circuit 212 may perform multiple refresh operations for each time REF or RFM is received and/or as part of a background refresh. For example, two, four, six, more or fewer refresh operations may be performed. In some example implementations, the refresh state control circuit 212 may perform only normal refresh operations responsive to REF and perform targeted refresh operations responsive to RFM. In some example implementations the refresh state control circuit 212 may perform a mix of normal and targeted refresh operations responsive to REF and perform targeted refresh operations responsive to RFM.

The refresh address generator 214 generates a refresh address RXADD responsive to IREF, RHR, or combinations thereof. For example, responsive to IREF, indicating a normal refresh address, the refresh address generator circuit 214 generates the refresh address RXADD based on sequence logic. For example, the refresh address generator circuit 214 may include a counter, which increments a value to generate a refresh address for normal refresh operations. Responsive to a targeted refresh operation (e.g., the signal RHR) the refresh address generator 214 uses an aggressor address HitXADD to generate one or more refresh addresses. For example, the refresh addresses may represent the word lines which are adjacent to the word line associated with HitXADD. In some embodiments, during a normal refresh operation multiple word lines may be refreshed, while during a targeted refresh operation a single word line may be refreshed. For example, the refresh address generated for a normal refresh operation may be truncated, and every word line which has an address which shares that truncated portion in common may be refreshed by the row decoder 202. Normal refreshes, targeted refreshes, or both may be performed as part of a background refresh operation.

When a word line is accessed, its associated PRAC value is read out to the ACU logic circuit 218. The row address XADD may indicate if it is associated with the bank portion 205a or the bank portion 205b. For example, a portion select bit of the row address may have a first state if the row address specifies the portion 205a or a second state if the row address specifies the portion 205b. In an example implementation, the bank may be organized such that all of the row addresses that have a most significant bit (MSB) at a logical high are in the portion 205a and all of the row addresses which have a MSB at a logical low are in the portion 205b. Accordingly, the most significant bit may act as the portion select bit.

Responsive to an activate command ACT, the row decoder 203 selected by the portion select bit of the row address activates a word line in the respective portion 205 for the access operation. The row decoder 203 not selected by the portion select bit also activates a word line to perform a background refresh operation in one or more rows of the unselected portion of the memory bank 204.

As part of an ACU operation, the ACU logic circuit 218 receives a PRAC value responsive to an activate command ACT. The ACU logic circuit 218 updates the PRAC value, for example by incrementing the PRAC value. If the PRAC value has not crossed a threshold, the updated PRAC value is written back to its original location in the bank 204. If the PRAC value has crossed a threshold, the ACU logic circuit 218 provides an aggressor signal AGG. In some embodiments, responsive to the PRAC value crossing the threshold, the ACU logic circuit 218 resets the PRAC value, for example to an initial value such as 0.

The aggressor register 216 includes a number of ‘slots’ which may be used to store aggressor addresses. For example, each slot may include a number of latch circuits the length of a row address. Responsive to the aggressor signal AGG, the register 216 adds the current row address XADD to the register. The register 216 may act as a first-in, first-out (FIFO) register in some embodiments.

As discussed herein, the quantity and distribution of traffic across the portions 205 may correlate with a number of refresh operations in memory devices implementing background refresh technology. For example, each access operation in the portion 205a may provide an opportunity for the refresh control circuit 210 to perform a background refresh operation in the portion 205b, and vice versa. As a result, when at least a threshold amount of traffic is provided to the memory bank 204, and when the traffic is equally balanced across the portions 205a and 205b, the memory bank 204 may be more likely to be adequately refreshed (e.g., as indicated by the refresh deficit count DeficitCnt 134 described with reference to FIG. 1). Correspondingly, a refresh flag associated with the memory bank 204 will be unlikely to be set at an active level when the memory bank 204 is adequately refreshed. As discussed herein, the disclosed technology may accordingly reduce the frequency at which the refresh flag is polled when the memory bank 204 is likely to be adequately refreshed, as indicated by the quantity and balance of the traffic to the memory bank 204.

FIG. 3 is a table 300 illustrating adjustable polling frequencies based on traffic balance according to embodiments of the disclosure. To define the polling frequencies, the table 300 provides polling schedules, which can be time periods during which at least one mode register read will be performed to read the refresh flag. The adjustable polling frequencies may be set by a polling logic circuit (e.g., 152 of FIG. 1) based at least in part on computed traffic balances. The polling logic circuit computes the traffic balances for traffic to a memory device (e.g., 100 of FIG. 1) based on comparing traffic count values to portions of a memory array (e.g., 118 of FIG. 1). As described herein, the memory device may set a refresh flag in a mode register (e.g., 130 of FIG. 1) to indicate to the memory controller that a refresh command is needed. The polling logic circuit of the memory controller determines when to perform a mode register read (MRR) to read the refresh flag. When the memory controller determines that the refresh flag is at an active level, the memory controller provides a refresh command to the memory device to cause performance of a standalone refresh.

The polling logic circuit may use a default frequency for polling the refresh flag, for example, when the frequency has not been adjusted based on a traffic balance or when the traffic balance is below a threshold (e.g., less than 25%). The default frequency may be provided by the mode register of the memory device. The default frequency is used to determine when the memory controller polls the refresh flag. The default frequency can be defined as a number of mode register reads during a time interval based on tREFI. For example, the polling logic circuit may cause the memory controller to poll the refresh flag once per tREFI unless the polling frequency is adjusted, as described herein. To adjust the polling frequency, a multiplier can be applied to the default frequency or to a time interval used to define the default frequency.

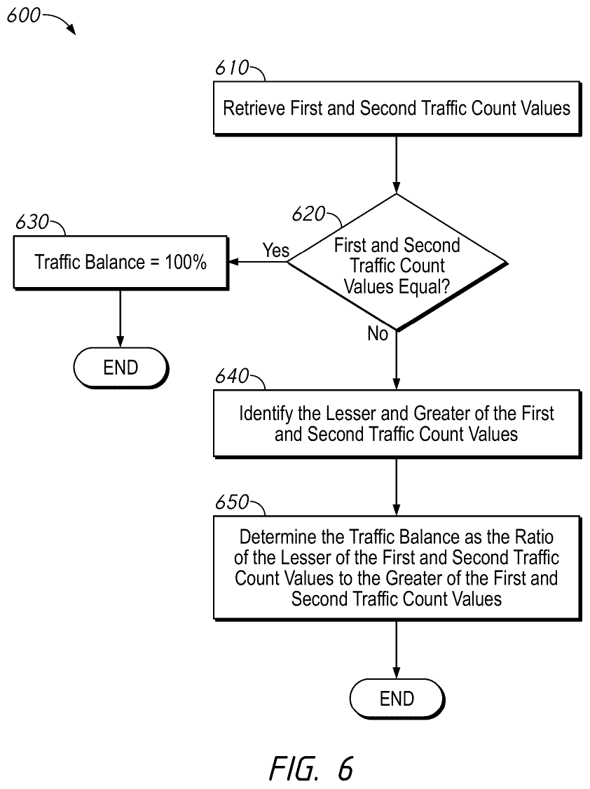

The polling logic circuit determines a traffic balance for traffic to portions of the memory device. For example, the traffic balance may indicate a distribution of traffic between two portions of a memory bank (e.g., 119a & 119b of FIGS. 1, 205a & 205b of FIG. 2). The traffic balance may be computed as a ratio of access operations between two portions of the memory device. The traffic balance may be computed based on traffic counters (e.g., 154 & 156 of FIG. 1). An example of computing a traffic balance is described with reference to FIG. 6.

As illustrated in the row 310 of FIG. 3, the polling logic circuit may compute a traffic balance of 25% between the two portions of the memory, which indicates that one of the portions of the memory array has received one access operation per four access operations received by the other portion of the memory array. When the traffic balance is 25%, the polling logic circuit sets the polling frequency such that the memory controller performs one mode register read to poll the refresh flag every two tREFI.

As illustrated in the row 320 of FIG. 3, the polling logic circuit may compute a traffic balance of 50% between the two portions of the memory, which indicates that one of the portions of the memory array has received one access operation per two access operations received by the other portion of the memory array. When the traffic balance is 50%, the polling logic circuit sets the polling frequency such that the memory controller performs one mode register read to poll the refresh flag every three tREFI.

As illustrated in the row 330 of FIG. 3, the polling logic circuit may compute a traffic balance of 75% between the two portions of the memory, which indicates that one of the portions of the memory array has received three access operation per four access operations received by the other portion of the memory array. When the traffic balance is 75%, the polling logic circuit sets the polling frequency such that the memory controller performs one mode register read to poll the refresh flag every four tREFI.

In some examples, the polling logic circuit may set different polling frequencies based on other computed traffic balance. In some examples, the polling logic circuit may set polling frequencies based on additional computed traffic balance. The polling logic circuit may pause polling of the refresh flag. In some examples, polling of the refresh flag is paused when the traffic balance is 100%, and polling of the refresh flag is resumed when the traffic balance is below 100%. In some examples, polling of the refresh flag is performed at a lower frequency when the traffic balance is 100%, such as once every five tREFI.

While example frequencies corresponding to traffic balances are illustrated with reference to the table 300 of FIG. 3, it will be appreciated that more or fewer frequencies can be used in various embodiments.

In various embodiments, the example frequencies illustrated with reference to the table 300 of FIG. 3 are applied when the total traffic to the memory device satisfies a threshold. The default frequency may be applied, regardless of traffic balance, when the total traffic is below the threshold. The total traffic may be computed as the sum of the traffic counters for the portions of the memory bank.

The table 300 may be stored and provided by a mode register (e.g., 130 of FIG. 1) of the memory device. The memory controller may read values of the table 300 from the mode register to determine polling frequencies for corresponding traffic balances. Additionally or alternatively, the table 300 may be stored at the memory controller.

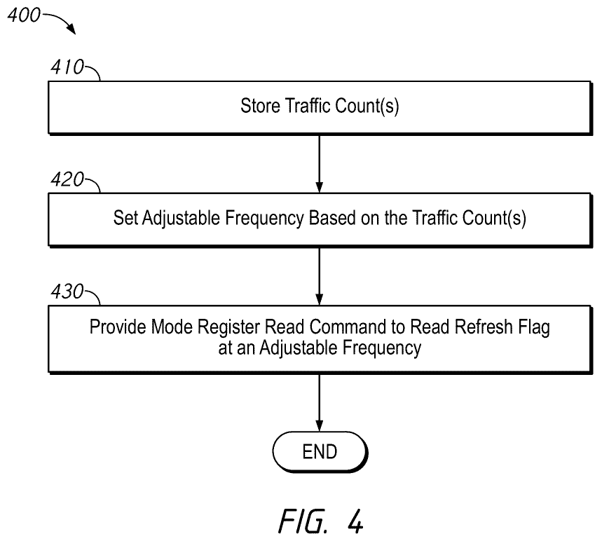

FIG. 4 is a flow diagram illustrating a process 400 for setting an adjustable polling frequency based on a traffic count according to embodiments of the disclosure. In some embodiments, the process 400 may be performed using a memory controller (e.g., 150 of FIG. 1) coupled to a memory device (e.g., 100 of FIG. 1).

The process 400 begins at block 410, where one or more traffic counts are stored. For example, a first traffic counter can store a first traffic count associated with access operations to a first portion of the memory device and a second traffic counter can store a second traffic count associated with access operations to a second portion of the memory device. In various embodiments, the traffic counts can be stored in FIFO buffers, such that they are iteratively updated to indicate an amount of traffic in a certain time period (e.g., as a multiple of tREFI).

The process 400 proceeds to block 420, where a polling logic circuit sets an adjustable frequency for performing mode register read commands to poll a refresh flag of the memory device. As described herein, the memory device provides a refresh flag, which is read by the memory controller, to indicate that a refresh command is needed. The refresh flag is based on a count of refresh operations performed at the memory device (e.g., compared to an expected number of refresh operations). For example, the refresh flag can comprise or be based on a refresh deficit count (e.g., DeficitCnt 134 of FIG. 1). The refresh flag is polled by the memory controller with timing that is determined by the polling logic circuit.

In various embodiments, the polling logic circuit applies a default frequency (e.g., one mode register read per tREFI) when the traffic balance is below a threshold, when total traffic is below a threshold, or both.

The polling logic circuit can track the total traffic to the memory device by summing the traffic counters, and the polling logic circuit can determine whether to adjust the polling frequency when the total traffic satisfies a threshold. For example, when the total traffic satisfies the threshold, the polling logic circuit may determine a traffic balance by comparing two or more traffic counters to determine a ratio of traffic between portions of the memory device. Based on the traffic balance, the polling logic circuit applies a corresponding frequency for polling the refresh flag, such as the frequencies illustrated with reference to the table 300 of FIG. 3.

In various embodiments, the polling frequency may be set based on total traffic, such that the polling frequency is decreased as the total traffic increases.

The process 400 proceeds to block 430, where the memory controller provides one or more mode register read commands to poll the refresh flag based on the frequency determined at block 430. As described herein, the disclosed technology allows the refresh flag to be polled less frequently (e.g., as compared to the default frequency) when the memory device is likely to be adequately refreshed, such as when the total traffic satisfies a threshold and when the traffic balance satisfies one or more thresholds.

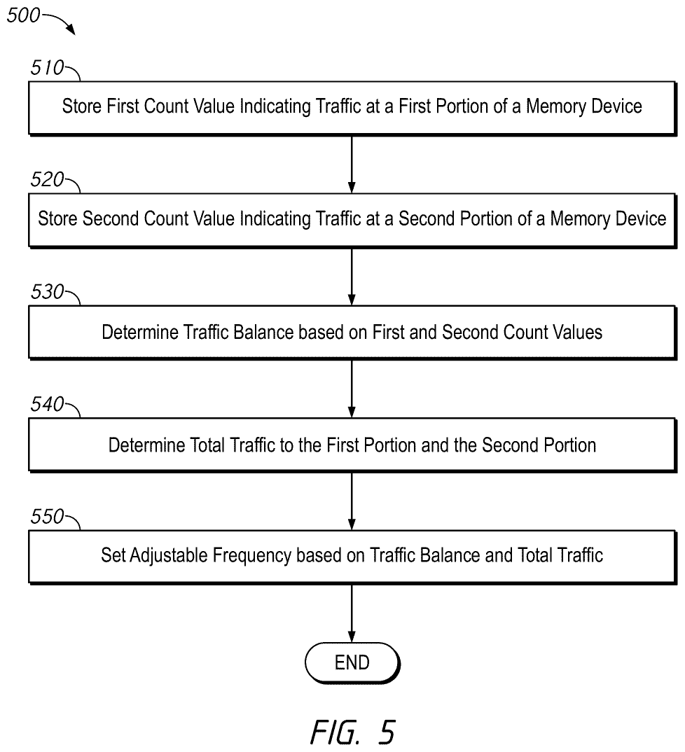

FIG. 5 is a flow diagram illustrating a process 500 for setting an adjustable polling frequency based on a traffic count and a traffic balance according to embodiments of the disclosure. The process 500 may be performed using a memory controller (e.g., 150 of FIG. 1) coupled to a memory device (e.g., 100 of FIG. 1).

The process 500 begins at block 510, where a first count value is stored indicating traffic at a first portion of the memory device. For example, the first count value can be stored using the traffic counter 154 of FIG. 1, and the first portion of the memory device can be the portion 119a of FIG. 1. The first count value indicates a number of access operations (e.g., in a time period) at the first portion of the memory device.

The process 500 proceeds to block 520, where a second count value is stored indicating traffic at a second portion of the memory device. For example, the second count value can be stored using the traffic counter 156 of FIG. 1, and the second portion of the memory device can be the portion 119b of FIG. 1. The second count value indicates a number of access operations (e.g., in the time period) at the second portion of the memory device.

The process 500 proceeds to block 530, where a traffic balance is determined based on the first count value and the second count value. The traffic balance can be a ratio of the first count value and the second count value. The traffic balance can be computed as illustrated with reference to FIG. 6.

The process 500 proceeds to block 540, where total traffic to the first and second portion of the memory device is computed. The total traffic can be the sum of the first count value and the second count value.

The process 500 proceeds to block 550, where an adjustable frequency for polling a refresh flag of the memory device is set based on the traffic balance and the total traffic. In various embodiments, a default frequency is used when the total traffic is below a first threshold, when the traffic balance is below a second threshold, or both. In various embodiments, a lower frequency (e.g., as compared to the default frequency) is set when the total traffic meets or exceeds the first threshold and when the traffic balance meets or exceeds the second threshold. In various embodiments, once the first threshold is satisfied, the polling frequency of the refresh flag is gradually decreased as the traffic balance increases. In these and other embodiments, polling can be paused when the traffic balance is 100%.

In various embodiments, the traffic balance may be computed when the total traffic meets or exceeds the first threshold, and the traffic balance is not computed when the total traffic is below the first threshold.

FIG. 6 is a flow diagram illustrating a process 600 for determining a traffic balance according to embodiments of the disclosure. In some embodiments, the process 600 may be performed using a memory controller (e.g., 150 of FIG. 1) coupled to a memory device (e.g., 100 of FIG. 1). In various embodiments, the process 600 is performed to determine a traffic balance when the total traffic (e.g., the sum of two or more traffic counters) exceeds a threshold value.

The process 600 begins at block 610, where first and second traffic count values are retrieved. For example, the first traffic count value can be retrieved from a traffic counter (e.g., 154 of FIG. 1) for a first portion (e.g., 119a of FIG. 1) of the memory device, and the second traffic count value can be retrieved from a traffic counter (e.g., 156 of FIG. 1) for a second portion (e.g., 119b of FIG. 1) of the memory device. The traffic count values are compared to determine the traffic balance.

The process 600 proceeds to decision block 620, where it is determined whether the first and second traffic count values are equal.

If the first and second traffic count value are equal, then the process 600 proceeds to block 630, where the traffic balance is determined to be 100%. In other words, the respective portions of the memory device have received the same amount of traffic during the respective time period, which indicates total balance. Upon determining the traffic balance, the process 600 ends, and the traffic balance can be used to set a polling frequency for reading a refresh flag of the memory device (e.g., as illustrated with reference to the table 300 of FIG. 3).

If, at block 620, it is determined that the first and second traffic count values are not equal, then the process 600 proceeds to block 640, where it is determined which of the traffic count values is greater and which is lesser.

The process 600 proceeds to block 650, where the traffic balance is determined as the ratio of the lesser traffic count value to the greater traffic count value.

Upon determining the traffic balance, the process 600 ends, and the traffic balance can be used to set a polling frequency for reading a refresh flag of the memory device (e.g., as illustrated with reference to the table 300 of FIG. 3).

It will be appreciated that operations of the processes 400, 500, and 600 can be added, omitted, combined, repeated, or performed in parallel while maintaining a similar functionality. While example embodiments are described with reference to a memory array or a memory bank divided into two portions, it will be appreciated that more or fewer portions can be used in other embodiments. In various embodiments, traffic balance and corresponding polling frequency can be determined per bank. In various embodiments, memory banks or memory arrays may be divided into more than two portions, and traffic balance can be evaluated across the portions to determine a polling frequency.

It is to be appreciated that any one of the examples, embodiments or processes described herein may be combined with one or more other examples, embodiments and/or processes or be separated and/or performed amongst separate devices or device portions in accordance with the present systems, devices, and methods.

Finally, the above discussion is intended to be merely illustrative of the present system and should not be construed as limiting the appended claims to any particular embodiment or group of embodiments. Thus, while the present systems, apparatuses, and methods have been described in particular detail with reference to example embodiments, it should also be appreciated that modifications and alternative embodiments may be devised by those having ordinary skill in the art without departing from the broader and intended spirit and scope of the present technology as set forth in the claims that follow. Accordingly, the present disclosure is to be regarded in an illustrative manner and is not intended to limit the scope of the appended claims.

What is claimed is:

1. An apparatus comprising:
a memory controller configured to provide a refresh command to a memory device responsive to a refresh flag at an active level, wherein the memory controller comprises:
a polling logic circuit configured to cause a read operation to read the refresh flag according to an adjustable frequency; and
at least one traffic counter configured to indicate access operations to a memory array of the memory device, wherein the adjustable frequency is set based on the at least one traffic counter.

2. The apparatus of claim 1, wherein the at least one traffic counter includes a first counter configured to indicate access operations to a first portion of the memory array of the memory device and a second counter configured to indicate access operations to a second portion of the memory array of the memory device.

3. The apparatus of claim 2, wherein the adjustable frequency is set based at least in part on a traffic balance computed by comparing a value of the first counter and the second counter.

4. The apparatus of claim 1, wherein the polling logic circuit is configured to set the adjustable frequency by applying a multiplier.

5. The apparatus of claim 1, wherein the adjustable frequency is set to a first value when the at least one traffic counter is below a threshold value, and wherein the adjustable frequency is set to a second value lower than the first value when the at least one traffic counter meets or exceeds the threshold value.

6. The apparatus of claim 1, wherein the adjustable frequency specifies a quantity of read operations in a time interval, and wherein the time interval is based on a refresh interval.

7. The apparatus of claim 1, wherein the refresh flag is received at the active level to indicate that at least one count value maintained at the memory device is below a threshold, and wherein the at least one count value maintained at the memory device indicates refresh operations at the memory array of the memory device.

8. The apparatus of claim 1, wherein the adjustable frequency is set based on a rate read from a mode register of the memory device.

9. The apparatus of claim 1, further comprising the memory device.

10. A system comprising:
a memory device comprising a mode register, a refresh control circuit, and a memory array, wherein the mode register is configured to store a refresh flag and the refresh control circuit is configured to activate the refresh flag based on one or more count values indicating refresh operations to the memory array;
a memory controller configured to read the refresh flag and provide a refresh command to the memory device when the refresh flag is activated, wherein the memory controller comprises adjustable polling logic configured to set a frequency of refresh flag reads based on at least one traffic counter, and wherein the at least one traffic counter indicates access operations to the memory array.

11. The system of claim 10, wherein the at least one traffic counter includes a first counter configured to indicate access operations to a first portion of the memory array of the memory device and a second counter configured to indicate access operations to a second portion of the memory array of the memory device.

12. The system of claim 11, wherein the adjustable polling logic is configured to set the frequency of the refresh flag reads based on a traffic balance computed by comparing a value of the first counter and the second counter.

13. The system of claim 10, wherein the adjustable polling logic is configured to set the frequency of the refresh flag reads by applying a multiplier.

14. The system of claim 10, wherein the frequency of the refresh flag reads is set to a first value when the at least one traffic counter is below a threshold value, and wherein the frequency of the refresh flag reads is set to a second value lower than the first value when the at least one traffic counter meets or exceeds the threshold value.

15. The system of claim 10, wherein the frequency of the refresh flag reads specifies a quantity of refresh flag reads in a time interval, and wherein the time interval is based on a refresh interval.

16. The system of claim 10, wherein the refresh control circuit is configured to activate the refresh flag when a count value of the one or more count values is below a threshold.

17. The system of claim 10, wherein the mode register is configured to store the frequency of the refresh flag reads, and wherein the adjustable polling logic is configured to read the frequency of the refresh flag reads from the mode register.

18. A method comprising:
storing a traffic count indicating access operations at a memory device;
providing, by a memory controller, a mode register read command to read a refresh flag of the memory device, wherein the mode register read command is provided according to an adjustable frequency; and
setting the adjustable frequency based on the traffic count.

19. The method of claim 18, wherein storing the traffic count includes storing a first traffic count indicating access operations to a first portion of a memory array of the memory device and a second traffic count indicating access operations to a second portion of the memory array of the memory device.

20. The method of claim 19, wherein the adjustable frequency is set based at least in part on a traffic balance computed by comparing the first traffic count and the second traffic count.

21. The method of claim 18, further comprising:
providing, by the memory controller, a refresh command responsive to the refresh flag.

22. The method of claim 18, further comprising:
providing a second mode register read command to read the adjustable frequency.

23. A method comprising:
computing, at a memory controller, a traffic balance of at least a portion of a memory device;
determining, at the memory controller, a frequency for performing refresh flag reads of a refresh flag of the memory device, wherein the frequency is based at least in part on the traffic balance;
providing, by the memory device, the refresh flag based on a quantity of refresh operations performed at a memory array of the memory device;
reading, by the memory controller, the refresh flag according to the frequency; and
providing, by the memory controller and to the memory device, a refresh command when the refresh flag is at an active level.

24. The method of claim 23, wherein the traffic balance is computed based on comparing a first traffic counter indicating access operations to a first portion of the memory device and a second traffic counter indicating access operations to a second portion of the memory device.

25. The method of claim 23, wherein the frequency is further based on a quantity of traffic to the memory device.
